(19) United States
(12) Patent Application Publication
(10) Pub. No.: US 2016/0329477 A1
(43) Pub. Date: Nov. 10, 2016

(54) THERMOELECTRIC DEVICE, IN PARTICULAR INTENDED FOR GENERATING AN ELECTRIC CURRENT IN AN AUTOMOTIVE VEHICLE

(71) Applicants: Georges DE PELSEMAEKER, Poigny-la-Foret (FR); Kamel AZZOUZ, Paris (FR)

(72) Inventors: Georges DE PELSEMAEKER, Poigny-la-Foret (FR); Kamel AZZOUZ, Paris (FR)

(21) Appl. No.: 14/901,813

(22) PCT Filed: Jul. 4, 2014
(86) PCT No.: PCT/EP2014/064368

§ 371 Date: Dec. 29, 2015

(30) Foreign Application Priority Data
Jul. 4, 2013 (FR) 13/01592

(51) Int. Cl. H01L 35/32; H01L 35/30; H01L 35/04

(52) U.S. Cl. CPC H01L 35/32; H01L 35/04; H01L 35/30

(57) ABSTRACT

The invention relates to a thermoelectric device comprising a plurality of thermoelectric modules each comprising at least one thermoelectric element of annular form, able to generate an electric current under the action of a temperature gradient exerted between two of its faces, the one, termed the first face, being defined by a surface of exterior periphery and the other, termed the second face, being defined by a surface of interior periphery, said device being configured so as to establish a thermal exchange between said first face and a first fluid and to establish a thermal exchange between said second face and a second fluid so that said first fluid and said second fluid circulate in a transverse manner with respect to one another, at least two of said modules forming a row of modules in which said modules are spaced apart according to a first direction parallel to a direction of circulation of the first fluid in the device and at least two of said modules forming a row of modules in which said modules are spaced apart according to a second direction, transverse to the first direction.

The present invention relates to a thermoelectric device, notably intended to generate an electric current in an automotive vehicle.

In the automotive field, thermoelectric devices have already been proposed, using so-called thermoelectric elements, giving the possibility of generating an electric current in the presence of a temperature gradient between two of their opposite faces according to the phenomenon known under the name of the Seebeck effect. These devices comprise a stack of first tubes, intended for the circulation of exhaust gases of an engine, and of second tubes, intended for the circulation of a heat transfer fluid of a cooling circuit. The thermoelectric elements are sandwiched between the tubes so as to be subject to a temperature gradient from the temperature difference between the hot exhaust gases and the cold coolant fluid.

Such devices are of particular interest since they give the possibility of producing electricity from conversion of heat from exhaust gases of the engine. They thus provide the possibility of reducing the fuel consumption of the vehicle by coming as at least partly as a substitution for the alternator usually provided in the latter for generating electricity from a belt driven by the crankshaft of the engine.

The owner has already developed ring-shaped thermoelectric elements, the temperature gradient allowing generation of the expected electric current being imposed between two of their opposite cylindrical faces. The hot fluid and the cold fluid then circulate co-axially, one circulating inside the ring and the other outside the ring. This solution however has integration difficulties which cause the engagement of a significant amount of material. In addition to the consequences on the price cost, such an engagement of material increases the thermal inertia of the device and therefore its efficiency, in particular its response time. Thus it may be unable to benefit from strong but too short heat increases.

The invention is proposed for improving the situation and for this purpose relates to a thermoelectric device comprising a plurality of thermoelectric modules each including at least one ring-shaped thermoelectric element, capable of generating an electric current under the action of a temperature gradient exerted between two of its faces, one, a so-called first face, being defined by an outer periphery surface and the other, a so-called second face, being defined by an inner periphery surface, said device being configured for establishing a heat exchange between said first face and a first fluid and for establishing a heat exchange between said second face and a second fluid so that said first fluid and said second fluid circulate transversely relatively to each other, at least two of said modules forming a row of modules in which said modules are spaced apart from each other along a first direction parallel to a circulation direction of the first fluid in the device and at least two of said modules forming a row of modules in which said modules are spaced apart from each other along a second direction, transverse to the first direction.

By the transverse orientation of the fluid circulation, it is possible to limit the engaged material, in particular on the side of the first fluid, in order to increase the exchange surface areas. The configuration in lines and rows further gives greater possibilities for positioning the different pipes intended to be connected to the module in order to supply it with fluid and thus facilitate its integration into its environment.

According to an aspect of the invention, said thermoelectric device is configured for allowing circulation of said first and second fluids, said second fluid having a greater heat exchange coefficient than said first fluid. The first fluid is notably exhaust gas. The second fluid for example is a liquid coolant.

The invention thus proposes a device, the efficiency of which is optimized by the fact that the exchange surface area is greater at the fluid having the smallest exchange coefficient. In this way, a more balanced ratio is available, between the heat resistance on the side of the first fluid, for example of the gas and the heat resistance on the side of the second fluid, notably of the liquid, promoting the operation of the assembly.

According to an exemplary embodiment of the invention, the second direction is perpendicular to the first direction and to a circulation direction of the second fluid in the device. The circulation of the second fluid in the device is carried out according to a third direction parallel to an axis defined by the ring shape of the thermoelectric elements.

Advantageously, the device comprises at least two lines and at least two rows of modules.

Advantageously, two rows of modules are spaced apart from each other along the first direction and two lines of modules are spaced apart from each other along the second direction.

According to an aspect of the invention, the neighboring modules of two adjacent rows are shifted relatively to each other along the second direction so as to be staggered. According to an alternative embodiment of the invention, the neighboring modules of two adjacent rows are located at the same level relatively to each other along the second direction so as to be positioned according to a grid.

According to an exemplary embodiment of the invention, the neighboring modules of two adjacent lines are shifted relatively to each other along the first direction so as to be staggered. According to an alternative embodiment of the invention, the neighboring modules of two adjacent lines are located at the same level along the first direction so as to be positioned according to a grid.

Advantageously, the device comprises a collecting box for inflow of the second fluid into the device and a collecting box for outflow of the second fluid from the device. The device may then comprise several circuits for passage of the second fluid through the modules between the inflow collecting box and the outflow collecting box, the circuits being independent of each other.

According to an aspect of the invention, each of the passage circuits comprises neighboring modules of each of the rows. Therefore there are as many independent passage circuits as there are modules in each row.

Advantageously, each of the passage circuits successively connects the neighboring rows as a coil.

According to an exemplary embodiment, the passage circuits comprise pipes connecting together the neighboring modules of two different rows, at their ends.

According to an embodiment of the invention, the collecting box of the outflow of the second fluid is located at a first module row intended to come into contact first with said first fluid and the inflow collecting box of the second fluid is located at a last module row intended to come into contact lastly with said first fluid.

According to an aspect of the invention, the inflow collecting box and the outflow collecting box are located on a same side of the device.

Advantageously, said thermoelectric device comprises secondary exchange surface areas with the first fluid, the secondary exchange surface areas being waved and/or perforated and/or fins with shutters. The fact that the fins are waved and/or perforated and/or with shutters gives the possibility of improving the heat exchange between the first fluid and the thermoelectric device of the invention, notably by increasing the exchange surface areas and by perturbing the flow of the first fluid. The fins are notably in metal.

According to an aspect of the invention, the cylinder formed by said thermoelectric elements is thinned in the direction of circulation of the first fluid so that it provides less resistance to the first fluid. The cylinder notably has a substantially oval-shaped base. The external thinned shape of the thermoelectric elements notably allows reduction of the aerodynamic master torque of the thermoelectric element and therefore reduction in the resistance to flow of the gases, this for a same total size.

Advantageously, said thermoelectric element has two opposite parallel planar faces.

According to an exemplary embodiment of the invention, each of the modules comprises a plurality of said thermoelectric elements. Said thermoelectric elements may be positioned relatively to each other so that their first and/or second surfaces are in the extension of each other.

According to an aspect of the invention, said thermoelectric elements are of two different types. Advantageously, said thermoelectric elements are here of a first type, so-called P type, giving the possibility of establishing an electric potential difference between said first and second faces, when they are subject to a given temperature gradient, and of a second type, so-called N type, giving the possibility of generating an electric potential difference in an opposite direction between said first and second faces, when they are subject to the same temperature gradient.

At least two thermoelectric elements of the same type may alternate along a longitudinal extension direction of the module, i.e. along the direction of circulation of the second fluid, with a thermoelectric element of the other type. Advantageously, said thermoelectric elements are positioned in the longitudinal extension of each other and the thermoelectric elements of type P alternate with the thermoelectric elements of type N.

According to an aspect of the invention, the thermoelectric elements are grouped pair-wise, formed with a so-called type P thermoelectric element and with a so-called N type thermoelectric element, said module being configured so as to allow current flow between the first surfaces of the thermoelectric elements of a same pair and a current flow between the second surfaces of each of the thermoelectric elements of said same pair and the neighboring thermoelectric element of the neighboring pair.

According to an aspect of the invention, said thermoelectric elements are of identical shape and dimension. In other words, they have an internal periphery, an external periphery and a thickness, i.e., a dimension along their longitudinal axis which are identical.

Alternatively, their thickness may be different, in particular depending on their electric conductivity. More specifically, the thermoelectric elements of type N may be more electrically conducting than the thermoelectric elements of type P, and the thickness of said thermoelectric elements of type N will be smaller than the thickness of the thermoelectric elements of type P, or vice versa. Thus the electric resistances of the thermoelectric elements of each of the types of thermoelectric elements may be more balanced, with a thinner thickness of thermoelectric elements of type N, or conversely of type P, and therefore savings in material.

According to an aspect of the invention, the module comprises first means for electric connection connecting the outer periphery surfaces of two of said thermoelectric elements, provided to be adjacent and of a different type, said secondary exchange surfaces being fixed on said first electric connection means. The secondary exchange surfaces are for example crimped with the first electric connection means. In another embodiment, they are brazed to said first electric connection means, notably by means of an electrically conducting braze.

Advantageously, the secondary exchange surfaces are crossed by said thermoelectric elements.

Advantageously, the secondary exchange surfaces extend in planes parallel to the circulation direction of the first fluid.

According to an aspect of the invention, the secondary exchange surfaces comprise a catalytic coating in order to ensure catalytic conversion of toxic components of the first fluid.

According to an aspect of the invention, the module comprises second electric connection means establishing an electric connection between the inner periphery surfaces of two of said thermoelectric elements, provided to be adjacent, of a different type and not connected through said first electric connection means.

Advantageously, said modules further comprise electric insulation means positioned between two adjacent thermoelectric elements of a different type, said electric insulation means being configured in order to electrically insulate from each other side faces of the thermoelectric elements connected through said first and/or second electric connection means and/or for electrically insulating from each other the secondary exchange surfaces connected to two of said thermoelectric elements, connected through the second electric connection means. Thus, the invention gives the possibility of limiting the risk of generating a short circuit between the secondary exchange surfaces.

According to an aspect of the invention, the modules each comprise a circulation channel of the second fluid in contact with said second surface of said thermoelectric elements.

Advantageously at least one of said channels extends along an off-centered axis with respect to a central axis of the cylinder formed by said thermoelectric elements. In particular, each of said channels extends along an off-centered axis relatively to said central axis of the cylinder formed by said thermoelectric elements.

According to an aspect of the invention, the off-centered axis of the channel is located in a plane defined by the central axis of the cylinder and the circulation direction of the first fluid. By orienting the thermoelectric elements relatively to the circulation direction of the first fluid, concentric electric equipotentials are thus available inside the thermo-elements.

Alternatively, at least one of the modules and notably all the modules may comprise a plurality of channels for circulation of cold liquid, notably parallel with each other, each channel cooperating with a plurality of thermoelectric elements each forming an angular section of a cylinder and positioned, one in the extension of the other along the longitudinal extension direction of the corresponding channel.

According to an exemplary embodiment of the invention, said secondary exchange surfaces connect the modules together so that they are crossed by said modules.

Advantageously, said device is configured so as to be positioned in an exhaust gas conduit of an automotive vehicle so that said secondary exchange surfaces are swept by said gases, the latter defining said first fluid.

The invention will be better understood in the light of the following description which is only given as an indication and which does not have the purpose of limiting it, accompanied by enclosed drawings wherein:

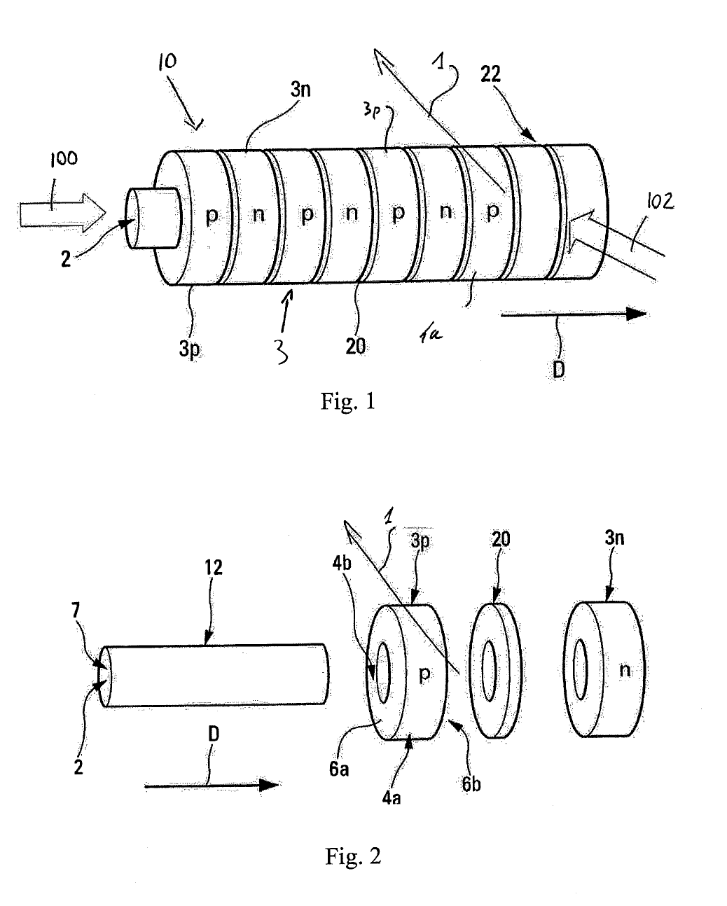

FIGS. 1 and 2 schematically illustrate in a perspective view, steps for mounting an exemplary module of a device according to the invention,

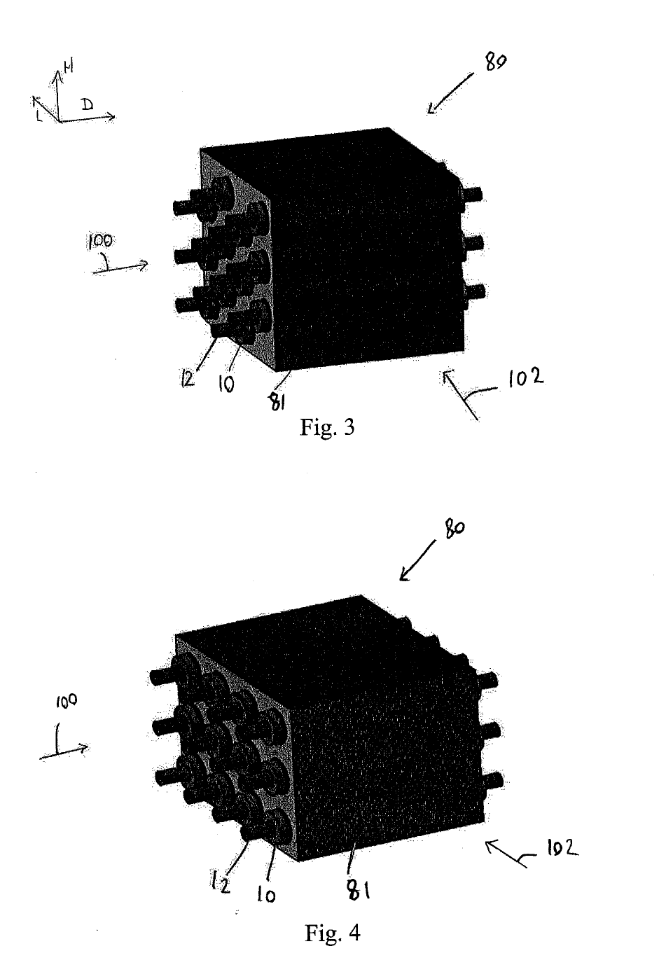

FIGS. 3 and 4 schematically illustrate, in a perspective view exemplary embodiments of a device according to the invention,

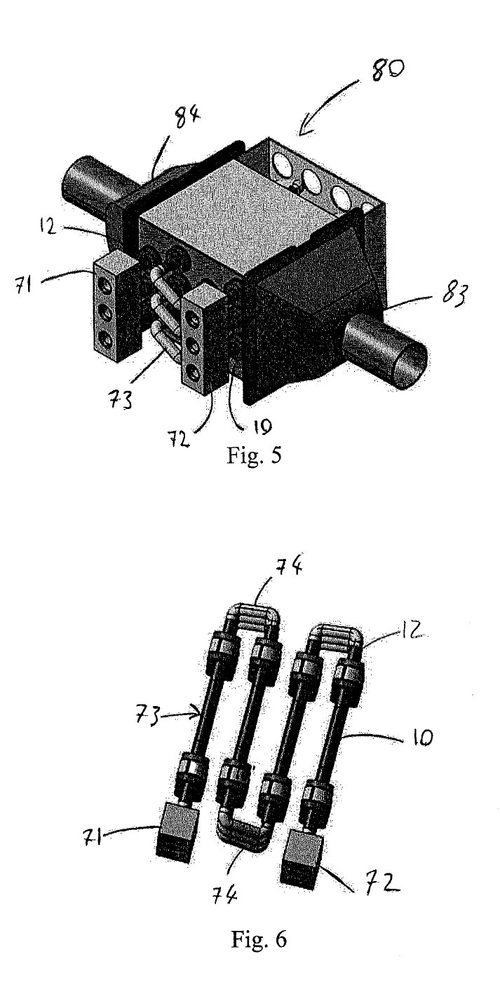

FIG. 5 illustrates as a perspective view an example of integration of the device of FIG. 4 in an exhaust line,

FIG. 6 schematically illustrates, in a perspective view, an exemplary circuit of circulation of the second fluid in the device illustrated in FIG. 5,

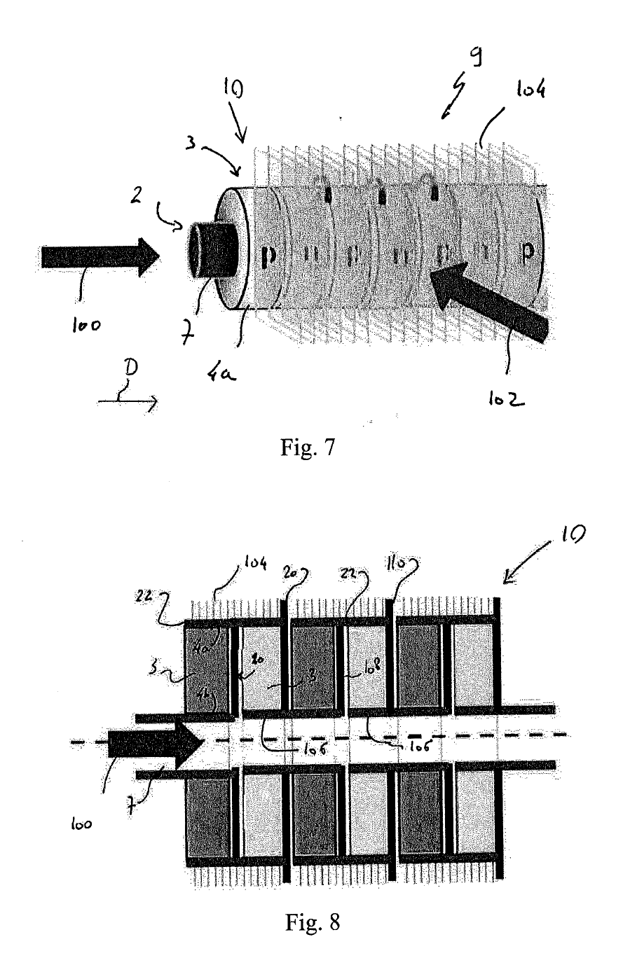

FIG. 7 schematically illustrates, in a perspective view, an exemplary module of a device according to the invention,

FIG. 8 schematically illustrates, along a longitudinal sectional plane, the module of FIG. 7,

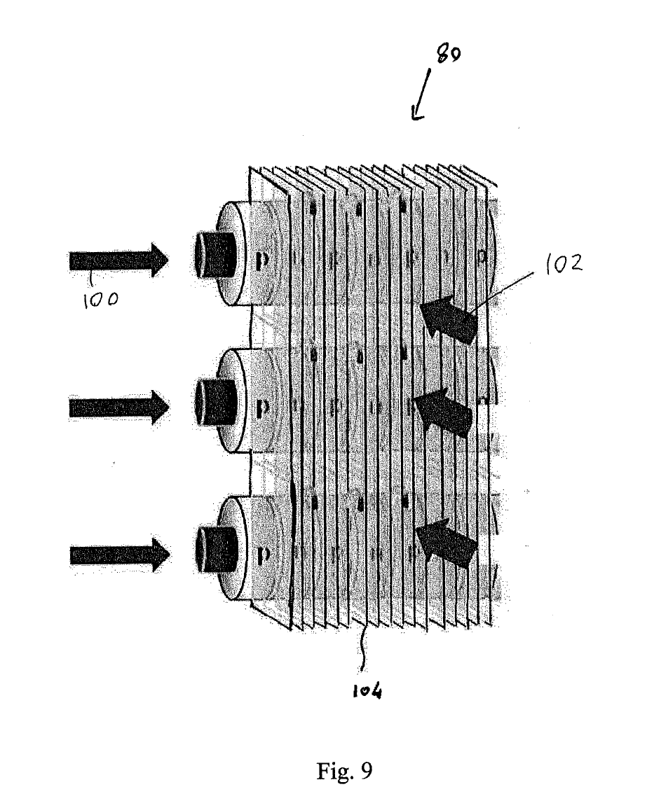

FIG. 9 schematically illustrates, in a perspective view, a row of modules of a device according to the invention,

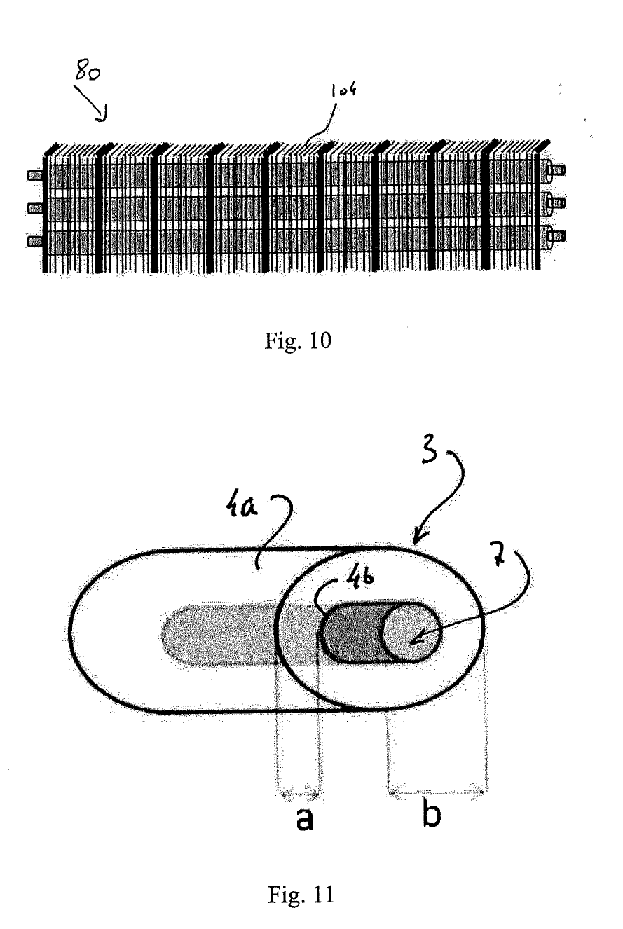

FIG. 10 schematically illustrates, in a perspective view, another exemplary embodiment of a row of modules,

FIG. 11 schematically illustrates, in a perspective view, a particularity of an exemplary embodiment of a module of a device according to the invention.

The invention relates to a thermoelectric device comprising a plurality of thermoelectric modules 10, one example of which is illustrated in FIGS. 1 and 2. Said module 10 here comprises a first so-called hot circuit 1 able to allow circulation of a first fluid, notably exhaust gases of an engine, and a second so-called cold circuit 2, able to allow circulation of a second fluid, notably a heat transfer fluid from a cooling circuit, with a temperature below that of the first fluid.

Said second fluid thus has a heat exchange coefficient greater than said first fluid.

The module 10 comprises at least one thermoelectric element, here a plurality of thermoelectric elements 3, ring-shaped, which may generate an electric current under the action of a temperature gradient exerted between two of its faces, one 4a, a so-called first face, being defined by a cylindrical outer periphery surface and the other 4b a so-called second face, being defined by a cylindrical inner periphery surface. As this will be developed subsequently, said first and second faces 4a and 4b are for example of an oval section for the first and/or circular for the second. More generally, any section with a rounded and/or polygonal shape is possible.

Such elements operate, according to the Seebeck effect, by allowing generation of electric current in a load connected between said faces 4a, 4b subject to the temperature gradient. In a way known to one skilled in the art, such elements for example consist of Bismuth and Tellurium (Bi₂Te₃).

The thermoelectric elements may for a first portion be 3p elements of a first type, a so-called P type, allowing establishment of an electric potential difference in one direction, a so-called positive direction, when they are subject to a given temperature gradient, and, for the other portion, elements 3n of a second type, a so-called N type, allowing generation of an electric potential difference in an opposite direction, a so-called negative direction, when they are subject to the same temperature gradient.

In FIGS. 1 and 2, the illustrated thermoelectric elements 3 consist of a ring in one piece. They may however be formed with several parts each forming an angular portion of the ring.

The first surface 4a for example has a radius comprised between 1.5 and 4 times the radius of the second surface 4b. This may be a radius equal to about twice that of the second surface 4b.

Said thermoelectric element for example has two opposite parallel planar faces 6a, 6b. In other words, the ring making up the thermoelectric element is of a rectangular annular section.

In the following, an example of association of thermoelectric elements together in the module according to the invention is described.

Said thermoelectric elements 3 are for example positioned in the longitudinal extension of each other, notably co-axially, and the thermoelectric elements of type P alternate with thermoelectric elements of type N, along a direction D, a so-called third direction D. They notably are of identical shape and dimension. They may however have a thickness, i.e. a dimension between both of their planar faces, different from one type to the other, notably depending on their electric conductivity.

Said thermoelectric elements 3 are for example, grouped pair-wise, each pair being formed with a so-called type P thermoelectric element and of a so called type N thermoelectric element, and said module is configured so as to allow current flow between the first surfaces of the thermoelectric elements of a same pair and a current flow between the second surfaces of each of the thermoelectric elements of said same pair and the thermoelectric element neighboring the neighboring pair. In this way, serial flow of the electric current is ensured between the thermoelectric elements 3 positioned beside each other along the direction D.

Again for facilitating the configuration of the circulation circuits of fluid 1, 2, it is possible to provide that said thermoelectric elements 3 are positioned relatively to each other so that their first and/or second surface 4a, 4b are in the extension of each other. Said first and/or second surfaces 4a, 4b are thus included for example in a surface generated by a straight line.

For the circulation of the fluids, the module according to the invention may comprise a channel 7 for circulation of a cold liquid in contact with said second surface 4b of said thermoelectric elements 3.

Said channel(s) 7 for circulation of liquid are for example of a circular section.

In FIG. 2, it is seen that said module comprises tubes 12 for circulation of cold liquid on which are mounted at least two thermoelectric elements of the same type alternating along the longitudinal extension direction D of the tube with a thermoelectric element of the other type. The tubes 12 are notably metal. They define at least partly the said channel 7.

Said module 10 may further comprise electric insulation means 20 positioned between two faces 6a, 6b facing neighboring thermoelectric elements 3 along the third direction D corresponding to the longitudinal extension direction of tube 12. In FIG. 2, the thermoelectric elements 3 and the electric insulation means 20 are assembled, alternately, on the tubes 12 for circulation of cold fluid.

Said module may further comprise first electric connection means 22 connecting the outer periphery surfaces 4a of two of said thermoelectric elements, provided adjacent and of different types. Said first electric connection means 22 for example comprise a layer of electrically conducting material, notably in copper and/or in nickel, of the coating of said thermoelectric elements 3.

According to the foregoing, the channel 7 for circulation of cold liquid is unique and placed at the centre of the module. According to an alternative, a plurality of channels for circulation of cold liquid may be provided in the extension of each other.

This being the case, as illustrated in FIG. 1, said module is configured so as to establish a heat exchange between said first face 4a and the first fluid, circulating here outside said thermoelectric elements 3 according to the illustrated arrow 102, and for establishing a heat exchange between said second face 4b and the second fluid, circulating here in the channel 7 along the illustrated arrow 100. The exchange between the thermoelectric elements 3 is thus promoted, and the fluid having the smallest heat exchange coefficient, here the exhaust gases.

Said module is further configured so that said first fluid and said second fluid circulate transversely, notably orthogonally with each other, as this is illustrated by the orientation of the arrows 100, 102. Such a configuration promotes the integration of the module in its environment by moreover decreasing the engaged amounts of material.

A thermoelectric device 80 comprising a plurality of said modules 10 according to the invention is illustrated in FIGS. 3 and 4. Such a thermoelectric device comprises at least two of said modules 10 forming a line of modules and at least two of said modules forming a row of modules. The modules 10 belonging to a same line of modules are spaced apart from each other along a first direction L and located at the same level along a second direction H transverse to the first. The modules 10 belonging to a same row of modules are spaced apart from each other along the second direction H and located at the same level along the first direction L.

The first direction L is notably parallel to the direction of circulation of the first fluid 102 in the device and the second direction H is perpendicular to the first direction L and to the direction of circulation of the second fluid 100 in the device.

The modules 10 thus extend longitudinally in the device 80 along the third direction D, are positioned in a line along the first direction L and in a row along the second direction H.

The first direction L, the second direction H and/or the third direction D are for example perpendicular to each other as illustrated in FIGS. 3 and 4.

In the examples illustrated in FIGS. 3 and 4, the device of the invention comprises several rows of modules 10 and several lines of module 10. Here, two rows of modules 10 are spaced apart from each other along the first direction L and two lines of modules are spaced apart from each other along the second direction H.

In the example illustrated in FIG. 3, the neighboring modules 10 of two adjacent rows are shifted relatively to each other along the second direction H in addition to being shifted along the first direction L so as to be staggered. By neighboring modules 10 of two adjacent rows are designated modules 10 which have the same position in their respective rows, i.e. the first modules of the rows starting from the bottom along the second direction H, the modules located just below the first modules etc. In this alternative embodiment of the invention, the rows of modules include the same number of modules and the lines of modules include one module less.

According to the exemplary embodiment of the invention illustrated in FIG. 3, the device of the invention comprises three rows of three modules 10 and six lines of two modules 10. Of course it may comprise a different number of rows and/or of lines as well as of modules 10 per row and/or of modules 10 per line.

In the exemplary embodiment illustrated in FIG. 4, the neighboring modules 10 of two adjacent rows are located at the same level relatively to each other along the second direction H so as to be positioned according to a grid. The neighboring modules 10 of two adjacent lines are located at the same level along the first direction L so as to be positioned according to a grid. Thus, the number of modules 10 which a row comprises is equal to the number of lines and the number of modules 10 which a line comprises is equal to the number of rows. In this example, the device 80 of the invention comprises four rows of three modules 10 each and three lines of four modules 10 each but of course it may comprise a different number of rows and/or of lines as well as of modules 10 per row and/or of modules 10 per line.

As illustrated in FIG. 5, the device of the invention may comprise an inflow collecting box 71 for the second fluid in the device 80 and an outflow collecting box 72 for the second fluid of the device, the device comprising several circuits 73 for the passing of the second fluid through the modules 10 between the inflow collecting box 71 and the outflow collecting box 72, the circuits 73 being independent of each other. The outflow collecting box 72 of the second fluid is located here at a first module row 10 intended to come into contact first with said first fluid, i.e. the row of modules 10 located as close as possible to the inflow face 81, and the inflow collecting box 71 for the second fluid is located at the level of a last row of modules 10 intended to come into contact lastly with said first fluid. In this way counter-current circulation is achieved. The inflow collecting box 71 and the outflow collecting box 72 are located on a same side of the device, here a lateral side of the device relatively to the inflow face of the first fluid into the device.

The device of the invention also comprises an inflow collecting box 83 for the first fluid in the device facing the inflow face for the first fluid into the device 80, and an outflow collecting box 84 for the second fluid, located opposite to the inflow collecting box 83 for the first fluid in the device relatively to the device.

According to the invention, each of the passage circuits 73 comprises neighboring modules 10 of each of the rows. Thus, there are as many independent circuits as there are modules 10 per row. Here, each of the circuits 73 successively connects the neighboring coil-shaped rows. The second fluid arrives in the inflow collecting box 71, enters one of the modules 10 of the row located at the inflow collecting box 71, crosses it in the direction of the length along the third direction D as seen earlier passes into a neighboring module 10 of an adjacent row and crosses it along the same direction but in the opposite sense. The second fluid continues its travel until it attains the outflow collecting box 72. In the example illustrated in FIG. 5, the device 80 has four rows and the second fluid therefore performs four passages before arriving in the outflow collecting box by circulating in the coil-shaped device 80.

As visible in more detail in FIG. 6, the passage circuits 73 comprise pipes 74 connecting together the neighboring modules 10 of two different rows, at their ends. These tubes notably have the shape of a U.

As illustrated in FIG. 7, said module advantageously comprises secondary exchange surfaces 9, in particular fins 104, with the first fluid. In this way the exchange surface area between the thermoelectric elements 3 and said first fluid is increased. Said fins 104 are for example positioned transversely in particular radially to said thermoelectric elements 3. They are here positioned parallel with each other with a distance allowing good heat exchange with the first fluid while limiting the pressure drops. Said fins 104 may be set off-center relatively to said thermoelectric elements 3, notably elongated on the side of the arrival of the first fluid.

Said fins 104 for example are waved, perforated and/or with shutters.

Said secondary exchange surfaces 9 may comprise a catalytic coating for ensuring catalytic conversion of toxic components of the first fluid. In the case of exhaust gases, said module may thus equip a catalytic converter as an addition to or as a substitute for the components conventionally used for catalysis in such pieces of equipment.

As illustrated in FIG. 8, said fins 104 are attached, for example, on said first electric connection means 22, notably by crimping and/or brazing.

The module may further comprise second electric connection means 106 establishing an electric connection between the inner periphery surfaces 4b of two of said thermoelectric elements 3 provided to be adjacent, of different types and not connected through said first electric connection means 22.

In other words, said first and second electric connection means 22, 106 connect pair-wise said thermoelectric elements 3 so as to establish electric flow in series between said thermoelectric elements of the module.

As already mentioned, the modules 10 advantageously comprise electric insulation means 20 positioned between two adjacent thermoelectric elements 3. Said electric insulation means are of two types. A first type 108 is configured so as to electrically insulate from each other the side faces of the thermoelectric elements connected through said first electric connection means 22. A second type 110 is configured for electrically insulating from each other the side faces of the thermoelectric elements connected through said second electric connection means 106 and/or for electrically insulating from each other the fins 104 bound to two of said thermoelectric elements, connected through the second electric connection means 106.

Such a configuration allows limitation of the short-circuit risks between the thermoelectric elements 3 which may occur via said fins 106.

As illustrated in FIG. 11, said channel 7 may extend along an axis off-centered relatively to a central axis of a cylinder formed by said thermoelectric elements 3, illustrated here as a single piece, for the sake of simplification. Said off-centered axis of the channel is for example located in a plane defined by the central axis of the cylinder and the direction of circulation of the first fluid. By thus varying the thickness of the thermoelectric elements 3 around the channel 7, a better distribution of the current equipotentials is obtained in the thermoelectric elements 3.

Alternatively or cumulatively, said cylinder is thin in the direction of circulation of the first fluid so that it provides less resistance to the first fluid. This being the case, alternatively, said first and/or second surfaces 4a, 4b may be coaxial. In other words, the thermoelectric element is provided with a constant radial thickness.

As illustrated in FIGS. 9 and 10, said fins 104 connect the modules together so that they are crossed by said modules. In these figures, only one of said rows is illustrated.

From an electrical point of view, the modules may be connected together in series and/or in parallel, through connections, not shown, located at their longitudinal ends.

As already mentioned, such a device may be configured so as to be positioned in an exhaust gas conduit of an automotive vehicle so that said secondary exchange surfaces are swept by said gases. In other words, the gases are intended to be channeled through the fins through the actual exhaust gas conduit while the circulation of the second fluid may be accomplished by inflow/outflow collecting boxes positioned sideways, whence great simplicity for integration.

Generally, it is understood that the invention, by having the hot fluid circulate outside the thermoelectric elements and transversely to the circulation of the cold fluid, gives the possibility of optimizing the heat exchange surfaces in contact with said thermoelectric elements, promoting the obtaining of high temperatures at the outer surface of said thermoelectric elements. It also promotes the implantation of equipped devices.

1. A thermoelectric device comprising a plurality of thermoelectric modules each including at least one ring-shaped thermoelectric element, capable of generating an electric current under the action of a temperature gradient exerted between two of its faces, one, a so-called first face, being defined by an outer periphery surface and the other, a so-called second face, being defined by an inner periphery surface, said device being configured for establishing a heat exchange between said first face and a first fluid and for establishing a heat exchange between said second face and a second fluid so that said first fluid and said second fluid circulate transversely relatively to each other, at least two of said modules forming a row of modules in which said modules are spaced apart from each other along a first direction parallel to a circulation direction of the first fluid in the device and at least two of said modules forming a row of modules in which said modules are spaced apart from each other along a second direction, transverse to the first direction.

2. The thermoelectric device according to claim 1, wherein the second direction is perpendicular to the first direction and to a circulation direction of the second fluid in the device.

3. The thermoelectric device according to claim 1, wherein the device comprises at least two lines and at least two rows of modules.

4. The thermoelectric device according to claim 3, wherein two rows of modules are spaced apart from each other along the first direction and two lines of modules are spaced apart from each other along the second direction.

5. The thermoelectric device according to claim 4, wherein the neighboring modules of two adjacent rows are shifted relatively to each other along the second direction so as to be staggered.

6. The thermoelectric device according to claim 4, wherein the neighboring modules of two adjacent lines are located at the same level relatively to each other along the second direction so as to be positioned according to a grid.

7. The thermoelectric device according to claim 4, wherein the neighboring modules of two adjacent lines are shifted relatively to each other along the first direction so as to be staggered.

8. The thermoelectric device according to claim 4, wherein the neighboring modules of two adjacent lines are located at the same level along the first direction so as to be positioned according to a grid.

9. The thermoelectric device according to claim 3, wherein the device comprises an inflow collecting box for the second fluid in the device and an outflow collecting box for the second fluid of the device, the device comprising several passage circuits for the second fluid through the modules between the inflow collecting box and the outflow collecting box, the circuits being independent of each other.

10. The thermoelectric device according to claim 9, wherein each of the passage circuits comprises neighboring modules of each of the rows.

11. The thermoelectric device according to claim 10, wherein each of the passage circuits successively connects the neighboring coil-shaped rows.

12. The thermoelectric device according to claim 10, wherein the passage circuits comprise pipes connecting together the neighboring modules of two different rows, at their ends.

13. The thermoelectric device according to claim 9, wherein the outflow connecting box for the second fluid is located at a first row of modules intended to first come into contact with said first fluid and the inflow collecting box for the second fluid is located at a last row of modules intended to lastly come into contact with said first fluid.

14. The thermoelectric device according to claim 13, wherein the inflow collecting box and the outflow collecting box are located on a same side of the device.

15. The device according to claim 1, comprising secondary exchange surfaces with the first fluid, the secondary exchange surfaces being waved and/or perforated fins and/or with shutters.
